(19) United States
(12) Patent Application Publication
(10) Pub. No.: US 2026/0189193 A1
(43) Pub. Date: Jul. 2, 2026

(54) AMPLIFIER DEVICE

(71) Applicant: RichWave Technology Corp., Taipei (TW)

(72) Inventors: Tien-Yun Peng, Taipei (TW); Sheng-Ting Chen, Taipei (TW); Chih-Sheng Chen, Taipei (TW)

(73) Assignee: RichWave Technology Corp., Taipei (TW)

(21) Appl. No.: 19/048,795

(22) Filed: Feb. 7, 2025

(30) Foreign Application Priority Data
Jan. 2, 2025 (TW) 114100053

(51) Int. Cl. H03F 1/30; H03F 3/70

(52) U.S. Cl. CPC H03F 1/301; H03F 3/70; H03F 2200/451; H03F 2200/468

(57) ABSTRACT

An amplifier device is provided. The amplifier device includes an inductor, a capacitor, an amplifier, a biasing circuit, and a driving circuit. The inductor and the capacitor are connected in series between a bias point and a first reference voltage terminal. The amplifier is coupled to the bias point to receive a bias signal. The biasing circuit generates a first benchmark voltage according to a bias reference signal and generates the bias signal at the bias point. The driving circuit includes a charging circuit and is coupled to the biasing circuit. The driving circuit controls the charging circuit according to the first benchmark voltage to provide a driving signal for charging the capacitor.

### CROSS-REFERENCE TO RELATED APPLICATION

This application claims the priority benefit of Taiwan application serial no. 114100053, filed on Jan. 2, 2025. The entirety of the above-mentioned patent application is hereby incorporated by reference herein and made a part of this specification.

### BACKGROUND

### Technical Field

The disclosure relates to a communication circuit design technology, and in particular relates to an amplifier device.

### Description of Related Art

Amplifiers are often used to amplify signals in wired or wireless communication technology. Since the signal transmission speed of requirements in the current communication technology, the signal processing frequency increases, thus the noise at the input terminal or bias terminal of the amplifier is increased. In order to reduce noise and avoid affecting the overall signal linearity of the circuit, a large-value capacitor is added to the input terminal or bias terminal of the amplifier.

However, the large-value capacitor may extend the time for the amplifier operating in the transient state, which causes the amplifier to require a longer transient processing time before reaching a steady state. Therefore, how to maintain the amplifier's signal linearity and a short transient processing time is one of the directions of technical research.

### SUMMARY

An amplifier device of the disclosure includes an inductor, a capacitor, an amplifier, and a driving circuit. The capacitor and the inductor are connected in series. The inductor and the capacitor are connected in series between a bias point and a first reference voltage terminal. The amplifier is coupled to the bias point to receive a bias signal. A biasing circuit generates a first benchmark voltage according to a bias reference signal and generates the bias signal at the bias point. The driving circuit includes a charging circuit and is coupled to the biasing circuit. The driving circuit controls the charging circuit according to the first benchmark voltage to provide a driving signal to charge the capacitor.

### BRIEF DESCRIPTION OF THE DRAWINGS

FIG. 1 is a block diagram of an amplifier circuit according to a first embodiment of the disclosure.

FIG. 2 is a circuit diagram of an amplifier circuit according to the first embodiment of the disclosure.

FIG. 3 is a circuit diagram of a driving circuit according to the first embodiment of the disclosure.

FIG. 4 is a detailed circuit diagram of the driving circuit of FIG. 3.

FIG. 5 is a block diagram of an amplifier circuit according to a second embodiment of the disclosure.

FIG. 6 is a circuit diagram of an amplifier circuit according to the second embodiment of the disclosure.

FIG. 7 is a circuit diagram of a driving circuit according to the second embodiment of the disclosure.

FIG. 8 is a detailed circuit diagram of the driving circuit of FIG. 7.

FIG. 9 is a block diagram of an amplifier circuit according to a third embodiment of the disclosure.

FIG. 10 is a circuit diagram of a driving circuit according to the third embodiment of the disclosure.

FIG. 11 is a circuit diagram of an amplifier circuit according to a fourth embodiment of the disclosure.

### DETAILED DESCRIPTION OF DISCLOSED EMBODIMENTS

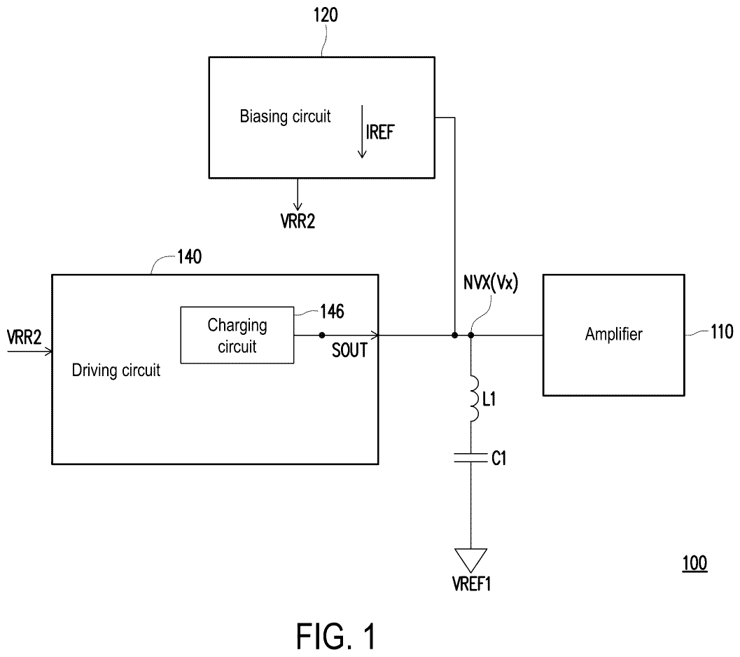

FIG. 1 is a block diagram of an amplifier circuit 100 according to a first embodiment of the disclosure. The amplifier circuit 100 includes an inductor L1, a capacitor C1, an amplifier 110, a biasing circuit 120, and a driving circuit 140. The capacitor C1 and the inductor L1 are connected in series. The inductor L1 and the capacitor C1 are connected in series between the bias point NVX and the reference voltage terminal VREF1 (e.g., the ground terminal). The reference voltage terminal VREF1 has a reference voltage (e.g., the ground voltage or the first reference voltage).

The amplifier 110 is coupled to the bias point NVX to receive the bias signal Vx at the bias point NVX. The biasing circuit 120 generates the benchmark voltage VRR2 according to a bias reference signal (e.g., the bias current IREF is taken as an example in this embodiment). Furthermore, the biasing circuit 120 generates the bias signal Vx at the bias point NVX.

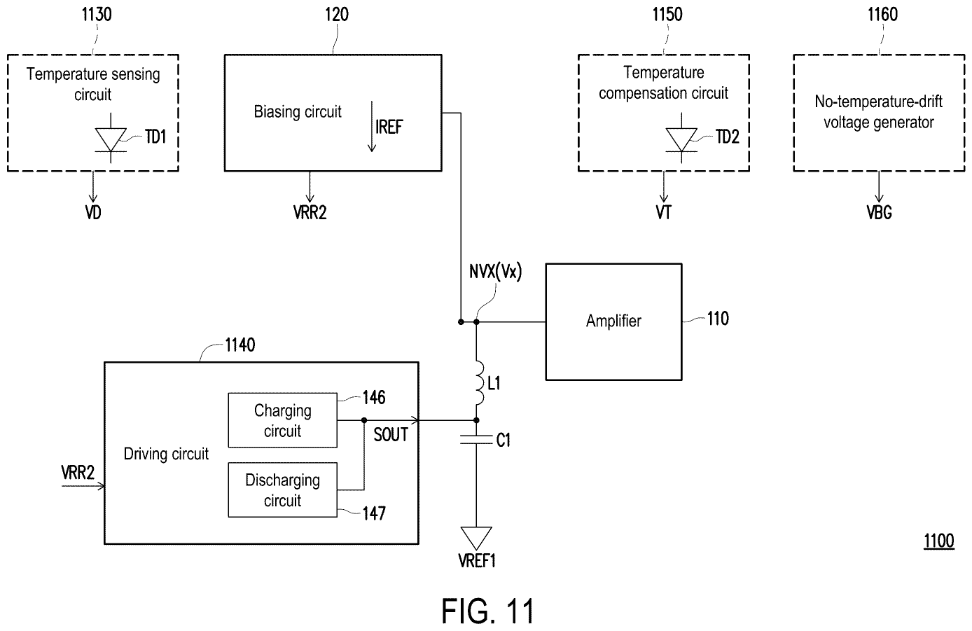

The driving circuit 140 includes the charging circuit 146. The driving circuit 140 is coupled to the biasing circuit 120. The driving circuit 140 controls the charging circuit 146 according to the benchmark voltage VRR2 to provide the driving signal SOUT to charge the capacitor C1. The driving circuit 140 in FIG. 1 is coupled to the bias point NVX to provide the driving signal SOUT to charge the capacitor C1. Those who apply this embodiment may also couple the driving circuit 140 to one terminal of the capacitor C1 to provide the driving signal SOUT to charge the capacitor C1, as shown in the driving circuit 1140 in FIG. 11 below.

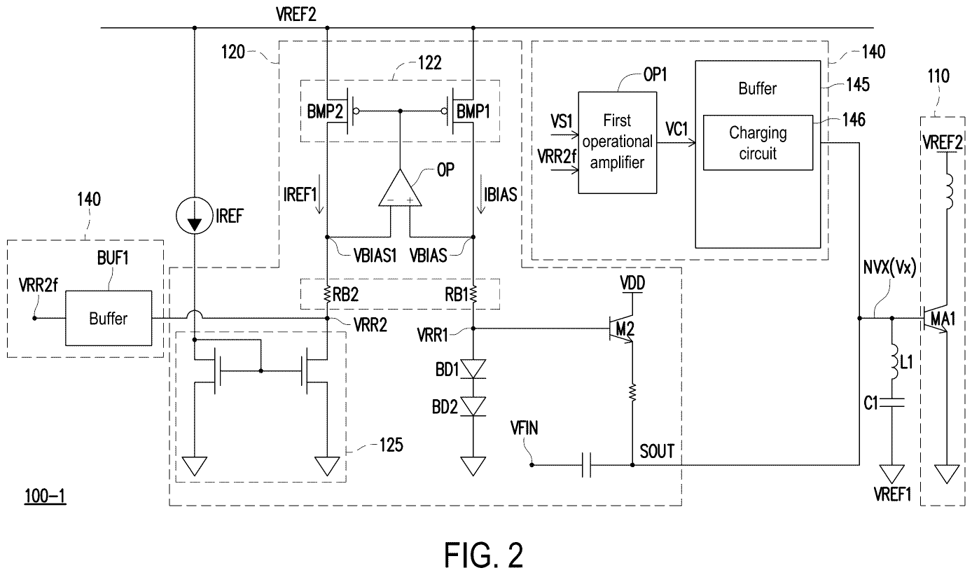

FIG. 2 is a circuit diagram of an amplifier circuit 100-1 according to the first embodiment of the disclosure. The amplifier circuit 100-1 of FIG. 2 is one implementation of the amplifier circuit 100 of FIG. 1. FIG. 2 mainly shows the detailed circuit structure of the amplifier 110, the biasing circuit 120, and the driving circuit 140. The amplifier 110 mainly includes a transistor MA1 used as an amplifier. One terminal (e.g., the collector terminal) of the transistor MA1 is coupled to the reference voltage terminal VREF2 through an inductor to receive the reference voltage (e.g., the system voltage VDD). The other terminal (e.g., the emitter terminal) of the transistor MA1 is coupled to the reference voltage terminal VREF1 (e.g., the ground terminal) for receiving the ground voltage (or, the first reference voltage). The control terminal (e.g., the base terminal) of the transistor MA1 is coupled to the bias terminal NVX to receive the bias signal Vx. In one embodiment, one terminal (e.g., the collector terminal) of the transistor MA1 is coupled to the reference voltage terminal (e.g., the third reference voltage terminal) through an inductor to receive the reference voltage (e.g., the system voltage VCC).

The biasing circuit 120 mainly includes a current mirror circuit 122, an operational amplifier OP, and a current mirror circuit 125. One terminal of the current mirror circuit 125 receives a bias reference signal (e.g., the bias current IREF) provided by a current source, and a current IREF1 is provided to the other terminal of the current mirror circuit 125 to the first branch of the current mirror circuit 122.

The current mirror circuit 122 includes a branch transistor BMP2 with a current IREF1 flowing through and a branch transistor BMP1 with a bias current IBIAS flowing through. In this embodiment, the branch transistor BMP2 and the branch resistor RB2 are referred to as the first branch of the current mirror circuit 122.

The second branch of the current mirror circuit 122 includes the branch transistor BMP1, the branch resistor RB1, and diodes BD1 and BD2. The first terminal (e.g., the drain terminal) of the branch transistor BMP1 is coupled to the reference voltage terminal VREF2 for receiving the reference voltage (e.g., the system voltage VDD). The second terminal (e.g., the source terminal) of the branch transistor BMP1 is coupled to one terminal of the branch resistor RB1. The other terminal of the branch resistor RB1 is coupled to one terminal (e.g., the anode terminal) of the diode BD1 and provides the benchmark voltage VRR1. The other terminal of the diode BD1 (e.g., the cathode terminal) is coupled to one terminal (e.g., the anode terminal) of the diode BD2. The other terminal of the diode BD2 (e.g., the cathode terminal) is coupled to the reference voltage terminal VREF1 (e.g., the ground terminal). The branch transistors BMP1 and BMP2 in this embodiment may be manufactured by silicon on insulator (SOI). The branch resistors RB1 and RB2 and the diodes BD1 and BD2 may be manufactured by gallium arsenide (GaAs).

The non-inverting input terminal of the operational amplifier OP is coupled to the second terminal of the branch transistor BMP1. The inverting input terminal of the operational amplifier OP is coupled to the second terminal of the branch transistor BMP2. The output terminal of the operational amplifier OP is coupled to the control terminals (e.g., the gate terminals) of the branch transistors BMP1 and BMP2.

This embodiment adjusts the transistor dimensions (e.g., the width W of the transistor channel, the inverse ratio 1/L of the length of the transistor channel, the width-to-length ratio W/L of the transistor channel) of the branch transistors BMP1 and BMP2. Specifically, the dimensions of the transistor BMP1 may be designed to be N times the dimensions of the transistor BMP2, so that the current value of the bias current IBIAS is equal to N times the current value of the current IREF1 (e.g., IBIAS=IREF1×N, N is a positive integer). Based on the virtual short-circuit effect of the operational amplifier OP, both the non-inverting input terminal and the inverting input terminal of the operational amplifier OP have the same voltage, that is, the voltage VBIAS1 is equal to the voltage VBIAS in principle.

Therefore, the first branch of the current mirror circuit 122 generates the benchmark voltage VRR2 based on at least the voltage VBIAS1, the current IREF1, and the branch resistor RB2. The benchmark voltage VRR2 is equal to the voltage VBIAS1 (equivalent to the voltage VBIAS) minus the value of the current IREF1 multiplied by the branch resistance RB2 (e.g., VRR2=VBIAS−IREF1×RB2).

The second branch of current mirror circuit 122 generates the benchmark voltage VRR1. The benchmark voltage VRR1 is equal to the voltage VBIAS minus the value of the bias current IBIAS multiplied by the branch resistance RB1 (e.g., VRR1=VBIAS−IBIAS×RB1).

The biasing circuit 120 also includes the transistor M2. The control terminal (e.g., the base terminal) of the transistor M2 receives the benchmark voltage VRR1, one terminal (e.g., the collector terminal) of the transistor M2 is coupled to the reference voltage terminal VREF2 to receive the reference voltage (e.g., the system voltage VDD or the second reference voltage), and the other terminal (e.g., the emitter terminal) of the transistor M2 is coupled to the bias terminal NVX through a resistor. The bias terminal NVX may also be coupled to the signal input terminal VFIN through a capacitor. The amplifier 110 receives the radio frequency signal from the signal input terminal VFIN and amplifies the radio frequency signal. The inductor L1 and the capacitor C1 form a resonant circuit and provide a lower impedance to the baseband signal compared to the radio frequency signal. In one embodiment, one terminal of the transistor T1 of the biasing circuit 120 is coupled to the reference voltage terminal VREF2 to receive the reference voltage (e.g., the system voltage VDD), and one terminal (e.g., the collector terminal) of the transistor MA1 of the amplifier 110 may be coupled to the reference voltage terminal VREF2 through the inductor L2 to receive the reference voltage (e.g., the system voltage VDD). In one embodiment, one terminal of the transistor T1 of the biasing circuit 120 is coupled to the reference voltage terminal VREF2 to receive the reference voltage (e.g., the system voltage VDD), and one terminal (e.g., the collector terminal) of the transistor MA1 of the amplifier 110 may be coupled to the circuit operating voltage terminal through the inductor L2 to receive the circuit operating voltage (e.g., VCC).

In this embodiment, a multiple K may be set between the impedance values of the branch resistor RB1 and the branch resistor RB2 (e.g., K=RB1/RB2). When the multiple K is 1/N, it means that the bias current IBIAS is equal to N times the current IREF1 and the impedance value of the branch resistor RB2 is N times the branch resistance RB1 (e.g., IBIAS=5×IREF1 & RB2=5×RB1). At this time, the benchmark voltage VRR1 may be equal to the benchmark voltage VRR2. The biasing circuit 120 of this embodiment may generate the benchmark voltage VRR2 according to the benchmark voltage VRR1, the multiple N between the transistor dimensions of the transistors BMP1 and BMP2 (or the multiple N between the current value of the bias current IBIAS and the current value of the current IREF1), and the multiple K between the branch resistor RB1 and the branch resistor RB2. In other words, the driving circuit 140 may generate the bias signal Vx according to the benchmark voltage VRR1.

The driving circuit 140 includes a buffer BUF1 that receives the benchmark voltage VRR2 and outputs the benchmark voltage VRR2f. The driving circuit 140 receives the benchmark voltage VRR2 through the buffer BUF1. The benchmark voltage VRR2f in this embodiment is equivalent to the benchmark voltage VRR2, and the buffer BUF1 is configured to maintain and transmit the benchmark voltage VRR2 to generate the benchmark voltage VRR2f.

The driving circuit 140 includes an operational amplifier OP1 and a charging circuit 146. The charging circuit 146 of this embodiment is disposed in the buffer 145. The first input terminal of the operational amplifier OP1 receives the reference signal VS1. The second input terminal of the operational amplifier OP1 receives the benchmark voltage VRR2f. The operational amplifier OP1 subtracts the reference signal VS1 from the benchmark voltage VRR2f to provide the control signal VC1 to the charging circuit 146.

The reference signal VS1 may be a signal generated based on the corresponding parameter detection circuit, so that the driving circuit 140 may generate an appropriate driving signal SOUT. In one embodiment, the reference signal VS1 may be related to the cross voltage from the control terminal to the second terminal of the transistor M2, so the driving circuit 140 may provide an appropriate driving signal SOUT according to the benchmark voltage VRR1 and the reference signal VS1. Specifically, the bias signal Vx provided by the second terminal of the transistor M2 will be similar to the driving signal SOUT provided by the driving circuit 140 (e.g., SOUT=VRR2−VS1=VRR1−V_{BEM2}, where V_{BEM2} is the voltage from the base terminal to the emitter terminal in the transistor M2), so that the amplifier device may appropriately bias the amplifier (e.g., the transistor MA1) and simultaneously charge the capacitor C1. In one embodiment, the reference signal VS1 may be generated from at least one of, or a combination of, the temperature signal provided by the ambient temperature sensing circuit, the temperature compensation signal provided by the temperature compensation circuit, the no-temperature-drift signal provided by the no-temperature-drift voltage generator (e.g., bandgap reference circuit), etc.

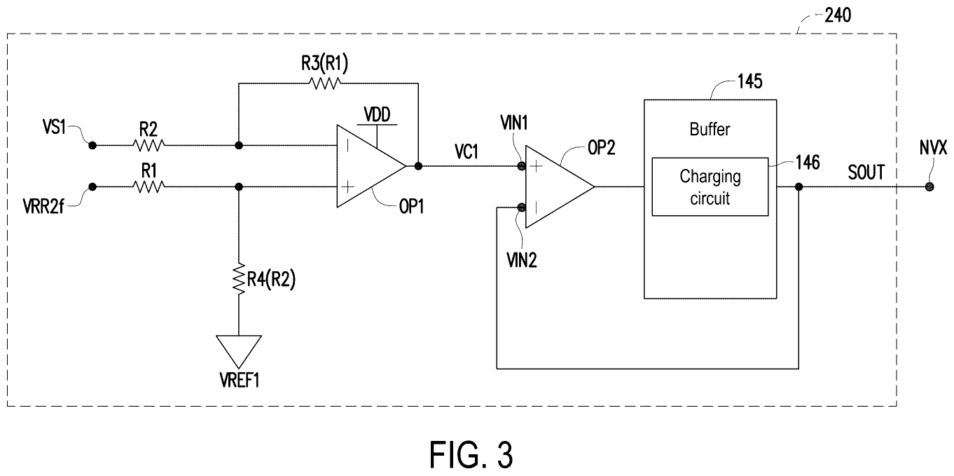

FIG. 3 is a circuit diagram of a driving circuit 240 according to the first embodiment of the disclosure. The difference between the driving circuit 240 of FIG. 3 and the driving circuit 140 of FIG. 2 is that the driving circuit 240 of FIG. 3 includes an operational amplifier OP2 in addition to the operational amplifier OP1, the buffer 145, and the charging circuit 146. The first input terminal (e.g., the non-inverting input terminal) of the operational amplifier OP2 receives the control signal VC1. The second input terminal (e.g., the inverting input terminal) of the operational amplifier OP2 is coupled to the bias point NVX and the output terminal of the charging circuit 146. The output terminal of the operational amplifier OP2 is coupled to the charging circuit 146. In this embodiment, the charging circuit 146 is controlled by the control signal VC1 to provide the driving signal SOUT to charge the capacitor C1.

The driving circuit 240 of FIG. 3 also includes resistors R1 to R4. The first input terminal (e.g., the non-inverting input terminal) of the operational amplifier OP1 receives the benchmark voltage VRR2 through the resistor R1. The first input terminal of the operational amplifier OP1 is also coupled to the reference voltage terminal VREF1 (e.g., the ground terminal) through the resistor R4. The second input terminal (e.g., the inverting input terminal) of the operational amplifier OP1 receives the reference voltage VS1 through the resistor R2. The second input terminal of the operational amplifier OP1 is coupled to the output terminal of the operational amplifier OP1 through the resistor R3. In this embodiment, the resistance value of the resistor R1 may be equal to the resistance value of the resistor R3, and the resistance value of the resistor R2 may be equal to the resistance value of the resistor R4. Moreover, the impedance values of the resistors R1 and R2 in FIG. 3 are respectively equal to the impedance values of the resistors R1 and R2 in FIG. 2.

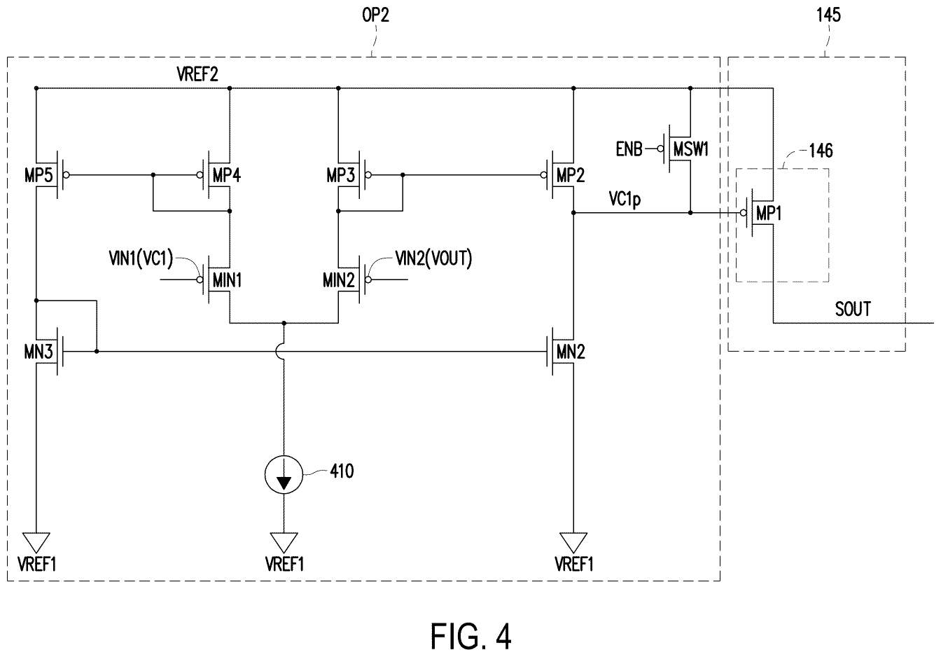

FIG. 4 is a detailed circuit diagram of the driving circuit 240 of FIG. 3. FIG. 4 mainly illustrates the circuit structure of the operational amplifier OP2 and the charging circuit 146. The operational amplifier OP2 includes transistors MP3, MN3, MP4, MP5 and a switching transistor MSW1 in addition to input transistors MIN1 and MIN2 and output transistors MN2 and MP2. The control terminal (e.g., the gate terminal) of the input transistor MIN1 serves as the input terminal VIN1 of the operational amplifier OP2 to receive the control signal VC1. The control terminal (e.g., the gate terminal) of the input transistor MIN2 serves as the input terminal VIN2 of the operational amplifier OP2 to receive the driving signal SOUT. According to the circuit structure of the operational amplifier OP2 in FIG. 4, the input terminal VIN1 and the driving signal SOUT, the control signal VC1p is generated at one terminal of the output transistor MP2. The switching transistor MSW1 includes a first terminal (e.g., the source terminal), a second terminal (e.g., the drain terminal), and a control terminal (e.g., the gate terminal). The first terminal of the switching transistor MSW1 is coupled to the reference voltage terminal VREF2 to receive the reference voltage (e.g., the system voltage VDD). The second terminal of the switching transistor MSW1 is coupled to the control terminal (e.g., the gate terminal) of the charging transistor MP1. The control terminal of the switching transistor MSW1 is configured to receive the enabling signal ENB. The amplifier device of this embodiment may enable or disable the driving circuit 240 according to the enabling signal ENB.

The first terminals (e.g., the source terminals) of the transistors MP3, MP4 and MP5 are coupled to the reference voltage terminal VREF2. The second terminal (e.g., the drain terminal) of the transistor MP3 is coupled to the control terminal (e.g., the gate terminal) of the transistor MP3, the control terminal of the transistor MP2, and the first terminal (e.g., the source terminal) of the input transistor MIN2. The second terminal (e.g., the drain terminal) of the transistor MP4 is coupled to the control terminal (e.g., the gate terminal) of the transistor MP4, the control terminal of the transistor MP5, and the first terminal (e.g., the source terminal) of the input transistor MIN1. The second terminals (e.g., drain terminals) of the input transistors MIN1 and MIN2 are coupled to the current source 410. The second terminal (e.g., drain terminal) of the transistor MP5 is coupled to the first terminal (e.g., the drain terminal) of the transistor MN3, the control terminal (e.g., the gate terminal) of the transistor MN3, and the control terminal (e.g., the gate terminal) of transistor MN2. The second terminals (e.g., source terminals) of the transistors MN2 and MN3 are coupled to the reference voltage terminal VREF1 (e.g., the ground terminal).

The charging circuit 146 includes the charging transistor MP1. The charging transistor MP1 includes a first terminal (e.g., a source terminal), a second terminal (e.g., a drain terminal), and a control terminal. The first terminal of the charging transistor MP1 is coupled to the reference voltage terminal VREF2. The second terminal of the charging transistor MP1 is coupled to the bias point NVX. The control terminal of the charging transistor MP1 receives the control signal VC1p and provides the driving signal SOUT according to the control signal VC1p to charge the capacitor C1. The driving signal SOUT may directly or indirectly generate a charging signal (e.g., a charging current) to charge one terminal of the capacitor C1. In this embodiment, the driving signal SOUT is the charging signal. In one embodiment, the charging transistor MP1 is a P-type field effect transistor.

Based on the circuit structure of the driving circuit 140 or the driving circuit 240 in FIG. 1 to FIG. 4, the driving voltage 140/240 provides the driving signal SOUT according to the benchmark voltage VRR1 (in this embodiment, the benchmark voltage VRR1 is equal to the benchmark voltage VRR2) and the reference signal VS1. In one embodiment, the benchmark voltage VRR2 may be further generated according to the multiple N between the current value of the current IBIAS in the biasing circuit 120 and the current value of the current IREF1 and the multiple K between the branch resistor RB1 and the branch resistor RB2, and the reference signal VS1 is further set, so that the amplifier device may appropriately bias the amplifier (e.g., the transistor MA1) and simultaneously charge the capacitor C1 (e.g., SOUT=VRR2−VS1=VRR1−V_{BEM2}, where V_{BEM2} is the voltage from the base terminal to the emitter terminal in the transistor M2). In this way, the amplifier devices (circuits) 100 and 100-1 charge the capacitor C1 located at the bias point NVX in real time by using the driving circuit 140/240 and the reference signal VS1 to reduce the transient processing time of the amplifier devices (circuits) 100 and 100-1, so that the operation of the amplifier circuits 100 and 100-1 is more stable.

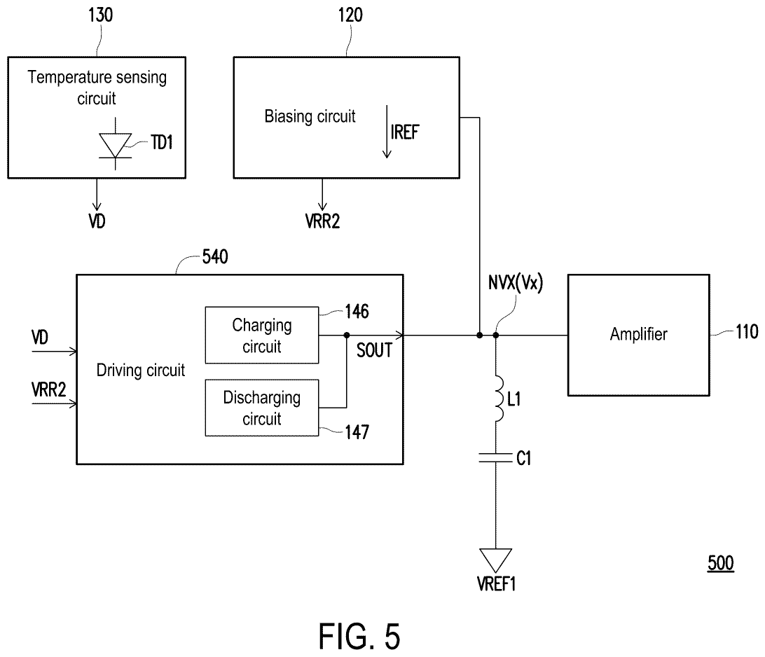

FIG. 5 is a block diagram of an amplifier circuit 500 according to a second embodiment of the disclosure. The main difference from the amplifier circuit 100 of FIG. 1 is that the amplifier circuit 500 of FIG. 5 also includes a temperature sensing circuit 130 and a discharging circuit 147. In other words, the amplifier circuit 500 of FIG. 5 uses the temperature sensing voltage VD provided by the temperature sensing circuit 130 as the reference signal VS1. Furthermore, a discharging circuit 147 is added in the amplifier circuit 500 in FIG. 5, and the driving circuit 540 controls the charging circuit 146 and the discharging circuit 147 according to the temperature sensing voltage VD and the benchmark voltage VRR2 to provide the driving signal SOUT to charge and/or discharge the capacitor C1. The temperature sensing circuit 130 includes a sensing diode TD1.

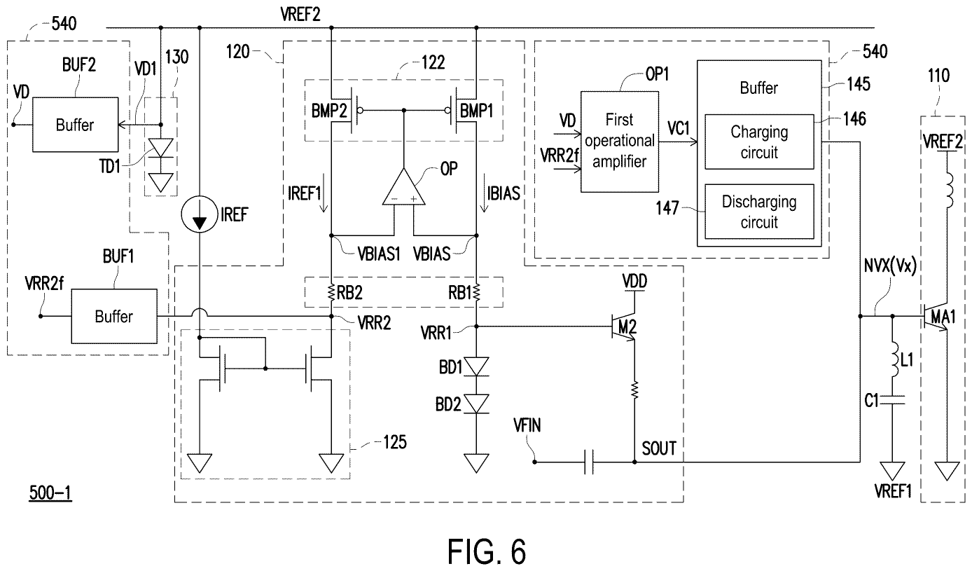

FIG. 6 is a circuit diagram of an amplifier circuit 500-1 according to the second embodiment of the disclosure. The amplifier circuit 500-1 of FIG. 6 is one implementation of the amplifier circuit 500 of FIG. 5. The main difference between FIG. 6 and FIG. 2 is that the amplifier circuit 500-1 of FIG. 6 also includes a discharging circuit 147 and a buffer BUF2 in the driving circuit 540. Furthermore, the amplifier circuit 500-1 of FIG. 6 also includes the circuit structure of the temperature sensing circuit 130. The discharging circuit 147 of this embodiment is disposed in the buffer 145.

The temperature sensing circuit 130 includes a sensing diode TD1 to correlate with the PN junction cross voltage. The first terminal of the sensing diode TD1 is coupled to the reference voltage terminal VREF2, and the second terminal of the sensing diode TD1 is coupled to the reference voltage terminal (e.g., the ground terminal). In response to changes in ambient temperature, the first terminal of the sensing diode TD1 provides a temperature sensing voltage VD. The sensing diode TD1 of this embodiment may be manufactured by gallium arsenide (GaAs).

The driving circuit 540 also includes a buffer BUF2. The driving circuit 540 receives the temperature sensing voltage VD through the buffer BUF2. The buffer BUF2 in this embodiment is configured to maintain and transmit the temperature sensing voltage VD. The operational amplifier OP1 subtracts the temperature sensing voltage VD from the benchmark voltage VRR2f to provide a control signal VC1 to the charging circuit 146 and the discharging circuit 147. That is, the operational amplifier OP1 performs a subtraction to calculate the difference between the temperature VD and the benchmark voltage VRR2f. The charging circuit 146 and the discharging circuit 147 provide a driving signal SOUT (e.g., a discharging signal or a discharging current) according to the control signal VC1. For the corresponding circuit structure of FIG. 6, reference may be made to FIG. 2 and the corresponding description.

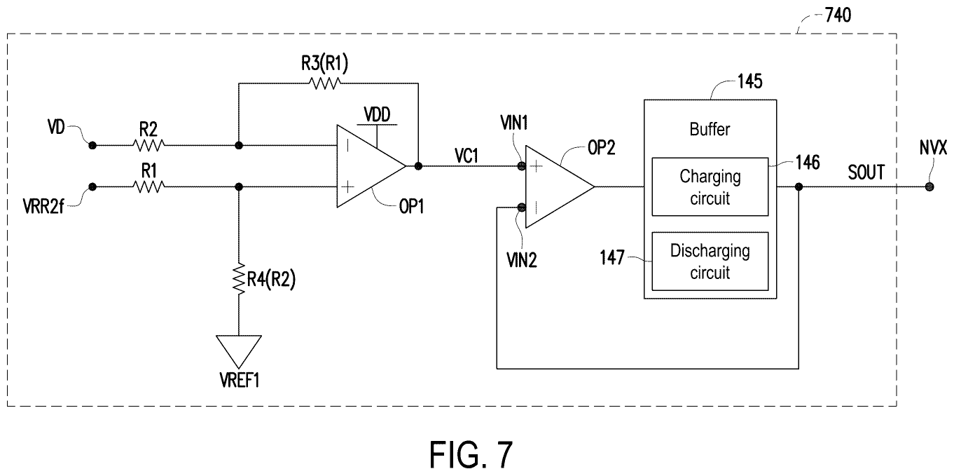

FIG. 7 is a circuit diagram of a driving circuit 740 according to the second embodiment of the disclosure. The difference between the driving circuit 740 of FIG. 7 and the driving circuit 540 of FIG. 6 is that the driving circuit 740 of FIG. 7 further includes an operational amplifier OP2. The coupling relationship of the operational amplifier OP2 in FIG. 7 is substantially the same as that of the operational amplifier OP2 in FIG. 3. The difference between the two is that the second input terminal (e.g., the inverting input terminal) of the operational amplifier OP2 receives the temperature sensing voltage VD through the resistor R2, rather than the reference voltage VS1. In this embodiment, the charging circuit 146 and the discharging circuit 147 are controlled by the control signal VC1 to provide the driving signal SOUT to charge and/or discharge the capacitor C1. For the corresponding circuit structure of FIG. 7, reference may be made to FIG. 3 and the corresponding description. In other words, the control signal VC1 adjusts the driving signal SOUT according to the temperature sensing voltage VD and the first benchmark voltage VRR2f to charge and/or discharge the capacitor C1.

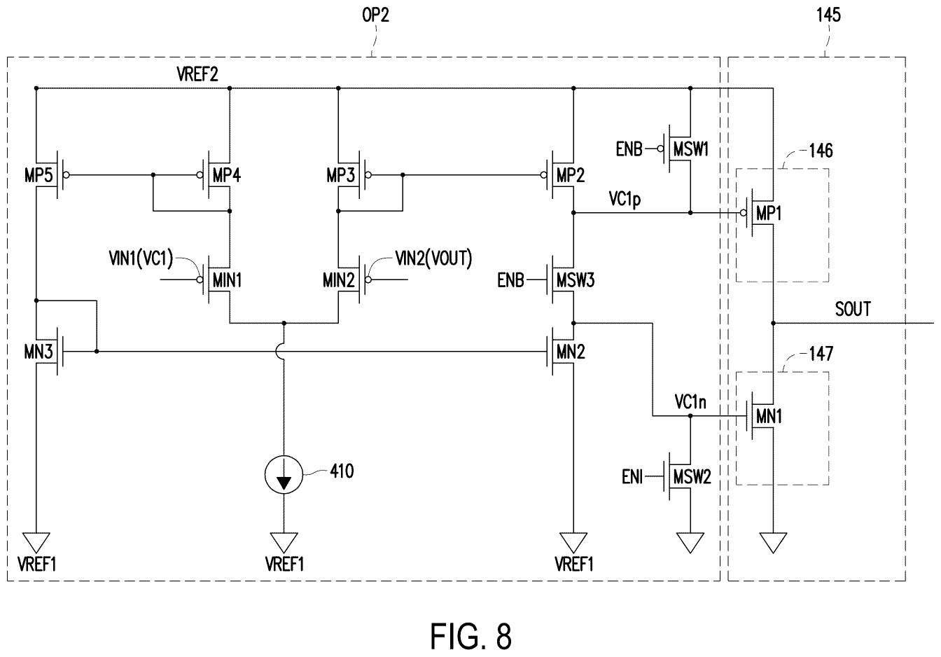

FIG. 8 is a detailed circuit diagram of the driving circuit 740 of FIG. 7. FIG. 8 mainly illustrates the circuit structure of the operational amplifier OP2, the charging circuit 146, and the charging circuit 147. For the circuit structure of the operational amplifier OP2 and the charging circuit 146, reference may be made to the above-mentioned FIG. 4 and the corresponding description. According to the circuit structure of the operational amplifier OP2 in FIG. 8, the input terminal VIN1 and the driving signal SOUT, the control signal VC1n is generated at one terminal of the output transistor MN2.

The operational amplifier OP2 in FIG. 8 also includes a switching transistor MSW2 and a switching transistor MSW3. The switching transistor MSW2 includes a first terminal (e.g., the source terminal), a second terminal (e.g., the drain terminal), and a control terminal (e.g., the gate terminal). The first terminal of the switching transistor MSW2 is coupled to the reference voltage terminal VREF1 (e.g., the ground terminal). The second terminal of the switching transistor MSW2 is coupled to the control terminal (e.g., the gate terminal) of the charging transistor MN1. The control terminal of the switching transistor MSW2 is configured to receive the enabling signal ENI. The switching transistor MSW3 includes a first terminal (e.g., the source terminal), a second terminal (e.g., the drain terminal), and a control terminal (e.g., the gate terminal). The first terminal of the switching transistor MSW3 is coupled to the control signal VC1p, the second terminal of the switching transistor MSW3 is configured to receive the control signal VC1n, and the control terminal of the switching transistor MSW3 is configured to receive the enabling signal ENB. In this embodiment, the enabling signal ENI and the enabling signal ENB are in inverse phase relationship to each other, that is, they are inverted enabling signals. The amplifier device of this embodiment may enable or disable the driving circuit 740 according to the enabling signal ENI and the enabling signal ENB. In one embodiment, when the enabling signal ENI and the enabling signal ENB enable the driving circuit 740, the switching transistor MSW3 is turned on, the switching transistor MSW1 and the switching transistor MSW2 are turned off, so that the control signal VC1p is equal to the control signal VC1n. In one embodiment, when the enabling signal ENI and the enabling signal ENB disable the driving circuit 740, the switching transistor MSW3 is turned off, the switching transistor MSW1 and the switching transistor MSW2 are turned on, so that the control signal VC1p is equal to the reference voltage (e.g., the system voltage VDD or the second reference voltage) and the control signal VC1n is equal to the ground voltage (e.g., the first reference voltage).

The discharging circuit 147 includes a discharging transistor MN1. The discharging transistor MN1 includes a first terminal (e.g., the source terminal), a second terminal (e.g., the drain terminal), and a control terminal (e.g., the gate terminal). The first terminal of the discharging transistor MN1 is coupled to the reference voltage terminal VREF1 (e.g., the ground terminal). The second terminal of the discharging transistor MN1 is coupled to the bias point NVX. The control terminal of the discharging transistor MN1 receives the control signal VC1p through the first terminal of the switching transistor MSW3 and the second terminal of the switching transistor MSW3. The discharging transistor MN1 provides a driving signal (e.g., a discharging signal or a discharging current) according to the control signal VC1n to discharge the capacitor C1. In one embodiment, the discharging transistor MN1 is an N-type field effect transistor.

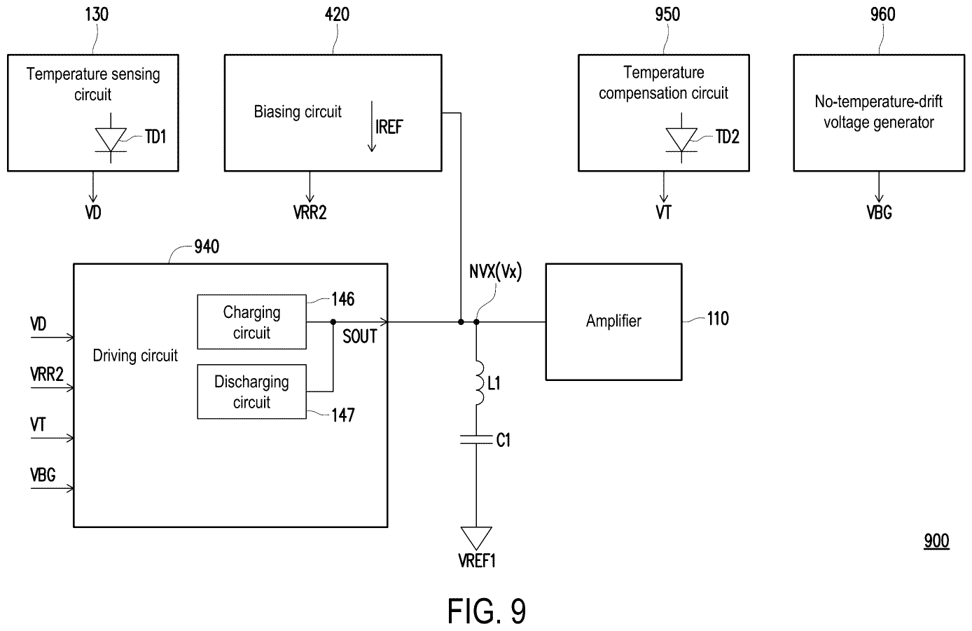

FIG. 9 is a block diagram of an amplifier circuit 900 according to a third embodiment of the disclosure. The main difference from the amplifier circuit 500 of FIG. 5 is that the amplifier circuit 900 of FIG. 9 also includes a temperature compensation circuit 950 and a no-temperature-drift voltage generator 960.

In other words, the amplifier circuit 900 in FIG. 9 generates an internal reference signal VS1 after operating the temperature sensing voltage VD provided by the temperature sensing circuit 130, the temperature compensation voltage VT (e.g. the compensation signal) provided by the temperature compensation circuit 950 (e.g. the compensation circuit), and the no-temperature-drift voltage VBG (e.g. the compensation signal) provided by the no-temperature-drift voltage generator 960 (e.g. the compensation circuit). In other words, the reference signal VS1 is related to the temperature sensing voltage VD, the temperature compensation voltage VT and the no-temperature-drift voltage VBG. The temperature compensation circuit 950 includes a compensation diode TD2 to correlate with the PN junction cross voltage. The compensation diode TD2 is disposed between the sensing diode TD1 and the amplifier 110 to detect temperature changes of the amplifier 110 and thereby provide a temperature compensation voltage VT as a compensation signal. The compensation diode TD2 in this embodiment may be implemented by a transistor. The driving circuit 940 generates a control signal VC1 according to the reference signal VS1 generated by the no-temperature-drift voltage VBG, the temperature compensation voltage VT, the temperature sensing voltage VD and the benchmark voltage VRR2 to control the charging circuit 146 and the discharging circuit 147 to charge and/or discharge the capacitor C1.

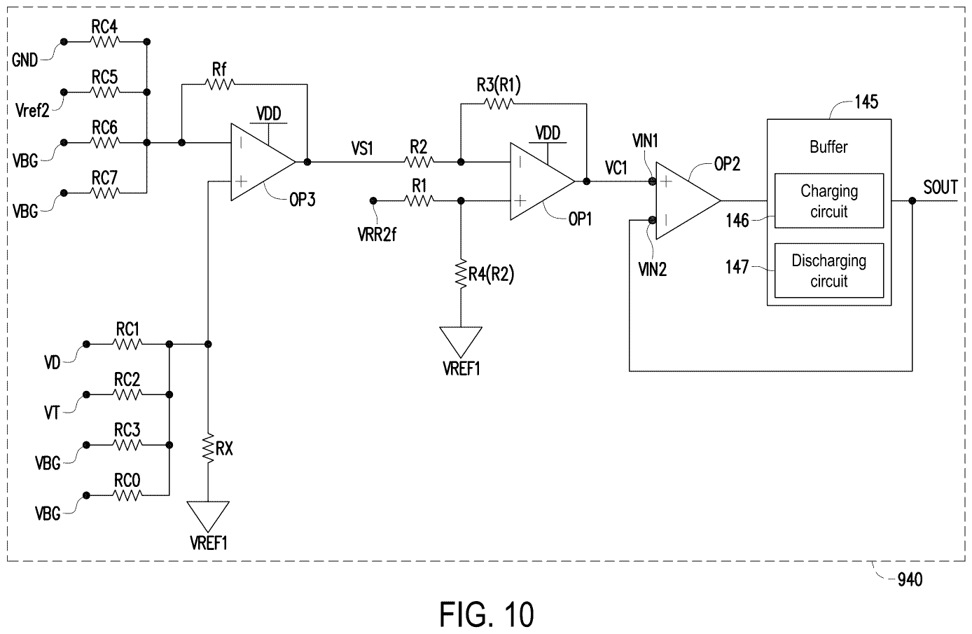

FIG. 10 is a circuit diagram of a driving circuit 940 according to the third embodiment of the disclosure. The driving circuit 940 of FIG. 10 also includes resistors RC0 to RC7, a resistor Rf, and a resistor Rx. The first input terminal (e.g., the non-inverting input terminal) of the operational amplifier OP3 receives the no-temperature-drift voltage VBG through the resistor RC0, receives the temperature sensing voltage VD through the resistor RC1, receives the temperature compensation voltage VT through the resistor RC2, receives the no-temperature-drift voltage VBG through the resistor RC3, and is coupled to the reference voltage terminal VREF1 (e.g., the ground terminal) through the resistor Rx. The second input terminal (e.g., the inverting input terminal) of the operational amplifier OP3 receives the ground signal GND through the resistor RC4, receives the reference voltage Vref2 on the reference voltage terminal VREF2 through the resistor RC5, receive the no-temperature-drift voltage VBG through resistor RC6, receive the no-temperature-drift voltage VBG through resistor RC7, and is coupled to the output terminal of the operational amplifier OP3 through the resistor Rf. The output terminal of the operational amplifier OP3 provides a reference signal VS1, in which the reference voltage Vref2 may serve as a compensation signal, and the reference voltage Vref2 may be configured to detect the offset of the system voltage VDD or VCC. In one embodiment, the resistor RC0 and the resistor RC4 have the same resistance value, the resistor RC1 and the resistor RC5 have the same resistance value, the resistor RC2 and the resistor RC6 have the same resistance value, and the resistor RC3 and the resistor RC7 have the same resistance value.

In this embodiment, the impedance values of the resistor Rf and the resistor RC0 may be set to have a multiple K0 (e.g., K0=Rf/RC0), the impedance values of the resistor Rf and the resistor RC1 may be set to have a multiple K1 (e.g., K1=Rf/RC1), the impedance values of the resistor Rf and the resistor RC2 may be set to have a multiple K2 (e.g., K2=Rf/RC2), and the impedance values of the resistor Rf and the resistor RC3 may be set to have a multiple K3 (e.g., K3=Rf/RC3). The driving voltage 940 of the disclosure generates the reference signal VS1 according to the no-temperature-drift voltage VBG, the reference voltage Vref2 (e.g., the system voltage VDD), the temperature compensation voltage VT, the temperature sensing voltage VD, and the multiples K0 to K3 (e.g., VS1=K0×VBG+K1×(VBG−Vref2)+K2×(VT−VBG)+K3×(VD−VBG)).

For details of the operational amplifier OP1, the operational amplifier OP2, the resistors R1 to R4, the buffer 145, the charging circuit 146, and the discharging circuit 147 in FIG. 10, reference may be made to the corresponding elements and corresponding descriptions of the driving circuit 740 in FIG. 7. In other words, the driving circuit 940 generates the control signals VC1p and VC1n according to the compensation signal (the reference voltage Vref2 and/or the temperature compensation voltage VT), the temperature sensing voltage VD, and the first benchmark voltage VRR2 to control the charging circuit 146 and the discharging circuit 147 to provide the driving signal SOUT to charge and discharge the capacitor C1. In one embodiment, the compensation signal may include a PN junction detection signal for detecting the offset of the manufacturing process.

FIG. 11 is a circuit diagram of an amplifier circuit 1100 according to a fourth embodiment of the disclosure. Compared with the previous embodiments, the driving circuit 1140 in the amplifier circuit 1100 in FIG. 11 is coupled to the first terminal of the capacitor C1 instead of being coupled to the bias point NVX. The temperature sensing circuit 1130, the temperature compensation circuit 1150, and the no-temperature-drift voltage generator 1160 may be selectively disposed in the amplifier circuit 1100 of FIG. 11 according to the requirements of those who apply this embodiment. The driving circuit 1140 generates the driving signal SOUT according to the reference signal generated by the selected compensation circuit, so that the amplifier circuit 1100 in FIG. 11 may provide the driving signal SOUT to charge the capacitor C1. Moreover, when the driving circuit 1140 in the amplifier circuit 1100 in FIG. 11 includes both the charging circuit 146 and the discharging circuit 147, the driving circuit 1140 provides the driving signal SOUT to charge and discharge the capacitor C1. In one embodiment, the driving circuits in FIG. 1, FIG. 5, and FIG. 9 may be coupled to the first terminal of the capacitor instead of being coupled to the bias point to generate a driving signal according to a reference signal generated by the selected compensation circuit, and provide the driving signal SOUT to the capacitor to charge the capacitor.

To sum up, the amplifier device of the embodiment of the disclosure charges and discharges a capacitor located at a bias point of the amplifier in real time by using a driving circuit and a related reference signal (e.g., ambient temperature variability, system voltage variability, manufacturing process variability, etc.) to reduce the transient processing time of the amplifier device, so that the operation of the amplifier circuit is more stable.

What is claimed is:

1. An amplifier device, comprising:
an inductor;
a capacitor, connected in series with the inductor, wherein the inductor and the capacitor are connected in series between a bias point and a first reference voltage terminal;
an amplifier, coupled to the bias point to receive a bias signal;
a biasing circuit, generating a first benchmark voltage according to a bias reference signal and generating the bias signal at the bias point; and
a driving circuit, comprising a charging circuit and coupled to the biasing circuit, wherein the driving circuit controls the charging circuit according to the first benchmark voltage to provide a driving signal to charge the capacitor.

2. The amplifier device according to claim 1, wherein the driving circuit is coupled to the bias point to provide a charging signal to charge the capacitor.

3. The amplifier device according to claim 1, wherein the driving circuit is coupled to one terminal of the capacitor to provide a charging signal to charge the capacitor.

4. The amplifier device according to claim 1, further comprising:
a temperature sensing circuit, comprising a sensing diode to provide a temperature sensing voltage.

5. The amplifier device according to claim 4, wherein the driving circuit further comprises a first operational amplifier,
a first input terminal of the first operational amplifier receives the temperature sensing voltage, a second input terminal of the first operational amplifier receives the first benchmark voltage, the first operational amplifier subtracts the temperature sensing voltage from the first benchmark voltage to provide a control signal to the charging circuit.

6. The amplifier device according to claim 4, wherein the charging circuit comprises a charging transistor,
the charging transistor comprises a first terminal and a second terminal, wherein the first terminal is configured to receive a second reference voltage, the second terminal is coupled to the bias point,
wherein the charging circuit provides a charging current according to a control signal, wherein the control signal adjusts the driving signal according to the temperature sensing voltage and the first benchmark voltage to charge or discharge the capacitor.

7. The amplifier device according to claim 6, wherein the driving circuit further comprises a discharging circuit,
wherein the discharging circuit comprises a discharging transistor,
the discharging transistor comprises a first terminal and a second terminal, wherein the first terminal is coupled to the bias point, the second terminal is coupled to the first reference voltage terminal, the discharging circuit provides a discharging current according to the control signal, wherein the control signal adjusts the driving signal according to the temperature sensing voltage and the first benchmark voltage to charge or discharge the capacitor,
wherein the driving circuit controls the charging circuit and the discharging circuit to provide the driving signal to charge and discharge the capacitor.

8. The amplifier device according to claim 6, wherein the driving circuit further comprises a first switching transistor, the first switching transistor comprises a first terminal, a second terminal, and a control terminal, wherein the first terminal is configured to receive the second reference voltage, the second terminal is coupled to a control terminal of the charging transistor, the control terminal is configured to receive an enabling signal.

9. The amplifier device according to claim 7, wherein the driving circuit further comprises:
a second switching transistor, the second switching transistor comprising a first terminal, a second terminal, and a control terminal, wherein the first terminal is coupled to the control terminal of the discharging transistor, the second terminal is coupled to the first reference voltage terminal, the control terminal is configured to receive an inverted enabling signal; and
a third switching transistor, the third switching transistor comprising a first terminal, a second terminal, and a control terminal, wherein the control terminal of the discharging transistor is configured to receive the control signal through the first terminal of the third switching transistor and the second terminal of the third switching transistor, the control terminal of the third switching transistor is configured to receive an enabling signal.

10. The amplifier device according to claim 8, wherein the amplifier device enables or disables the driving circuit according to the enabling signal.

11. The amplifier device according to claim 5, wherein the driving circuit comprises a first resistor, a second resistor, a third resistor, and a fourth resistor, wherein the first input terminal of the first operational amplifier receives the first benchmark voltage through the first resistor, the first input terminal of the first operational amplifier is coupled to the first reference voltage terminal through the fourth resistor, the second input terminal of the first operational amplifier receives the temperature sensing voltage through the second resistor, the second input terminal of the first operational amplifier is coupled to an output terminal of the first operational amplifier through the third resistor,
wherein a resistance value of the first resistor is equal to a resistance value of the third resistor, and a resistance value of the second resistor is equal to a resistance value of the fourth resistor.

12. The amplifier device according to claim 7, wherein the driving circuit further comprises a second operational amplifier, wherein a first input terminal of the second operational amplifier receives the control signal, a second input terminal of the second operational amplifier is coupled to the bias point, an output terminal of the second operational amplifier is coupled to the charging circuit and the discharging circuit, to control the charging circuit and the discharging circuit to provide the driving signal to charge and discharge the capacitor.

13. The amplifier device according to claim 1, wherein the biasing circuit comprises a first current mirror circuit, wherein the first current mirror circuit comprises a first branch and a second branch, wherein the first branch generates the first benchmark voltage, the second branch generates a second benchmark voltage, wherein the driving circuit generates the bias signal according to the second benchmark voltage.

14. The amplifier device according to claim 13, wherein the second branch comprises a branch transistor, a branch resistor, a first diode, and a second diode, wherein a first terminal of the branch transistor is configured to receive a second reference voltage, a second terminal of the branch transistor is coupled to one terminal of the branch resistor, another terminal of the branch resistor is coupled to one terminal of the first diode and provides the second benchmark voltage, another terminal of the first diode is coupled to one terminal of the second diode, another terminal of the second diode is coupled to the first reference voltage terminal, wherein the first benchmark voltage is equal to the second benchmark voltage.

15. The amplifier device according to claim 14, wherein the branch transistor is manufactured by silicon on insulator (SOI), and the branch resistor, the first diode, and the second diode are manufactured by gallium arsenide (GaAs).

16. The amplifier device according to claim 1, wherein the driving circuit comprises a first buffer, the driving circuit receives the first benchmark voltage through the first buffer, and the driving circuit comprises a second buffer, the driving circuit receives a temperature sensing voltage through the second buffer.

17. The amplifier device according to claim 4, wherein the sensing diode is manufactured by gallium arsenide (GaAs).

18. The amplifier device according to claim 4, further comprising:
a temperature compensation circuit, comprising a compensation diode, wherein the compensation diode provides a temperature compensation voltage,
wherein the compensation diode is disposed between the sensing diode and the amplifier,
wherein the driving circuit generates a control signal according to a no-temperature-drift voltage, the temperature compensation voltage, the temperature sensing voltage, and the first benchmark voltage to control the charging circuit to charge the capacitor.

19. The amplifier device according to claim 7, wherein the driving circuit comprises a compensation circuit, the compensation circuit is configured to generate a compensation signal, the driving circuit generates the control signal according to the compensation signal, a temperature sensing voltage, and the first benchmark voltage to control the charging circuit and the discharging circuit to provide a driving signal to charge and discharge the capacitor, wherein the control signal is correlated with at least one of a second reference voltage, a temperature, and a PN junction cross voltage.

20. The amplifier device according to claim 1, wherein the amplifier receives a radio frequency signal and amplifies the radio frequency signal, the inductor and the capacitor form a resonant circuit and provide a lower impedance to a baseband signal compared to the radio frequency signal.
